(19) United States
(12) Patent Application Publication
(10) Pub. No.: US 2015/0136448 A1
(43) Pub. Date: May 21, 2015

(54) Flexible Printed Wiring Board and Electronic Apparatus

(71) Applicant: Kabushiki Kaisha Toshiba, Tokyo (JP)

(72) Inventor: Kazuyoshi Sasaki, Ome-shi (JP)

(21) Appl. No.: 14/459,134

(22) Filed: Aug. 13, 2014

Related U.S. Application Data
(60) Provisional application No. 61/905,795, filed on Nov. 18, 2013.

(51) Int. Cl. H05K 1/02; H05K 1/11

(52) U.S. Cl. CPC H05K 1/028; H05K 1/0298; H05K 1/115; H05K 2201/055
USPC 174/251

(57) ABSTRACT

According to one embodiment, a flexible printed wiring board includes a first conductor layer formed on the first surface of an insulation base, a second conductor layer formed on the second surface of the insulation base, a first insulation layer covering the first conductor layer, and a second insulation layer covering the second conductor layer. The first insulation layer has an opening formed in a position corresponding to a connecting terminal portion to expose the first conductor layer. A metal layer is provided in a region ranging from the connecting terminal portion to a bending presumed portion. The metal layer is positioned behind the opening between the second surface and the second insulation layer to avoid the first conductor layer.

### CROSS-REFERENCE TO RELATED APPLICATIONS

This application claims the benefit of U.S. Provisional Application No. 61/905,795, filed Nov. 18, 2013, the entire contents of which are incorporated herein by reference.

### FIELD

Embodiments described herein relate generally to a flexible printed wiring board and an electronic apparatus.

### BACKGROUND

Flexible printed wiring boards are now being widely used as wiring components for electronic apparatuses, such as portable computers. In recent flexible wiring boards, there are increasing demands for fine wiring specifications and high-speed transmission characteristics in accordance with thinning of the electronic apparatuses and enhancement of functionality of the electronic apparatuses.

In particular, in double-sided flexible printed wiring boards, where, for example, the thickness of a connecting terminal portion to be connected to a connector is designated, patterned conductors are eliminated from the reverse side of the connecting terminal portion, and an insulation layer is eliminated from the obverse side of the connecting terminal portion to expose end portions of the patterned conductors.

In double-sided flexible printed wiring boards in which the number of patterned conductors is small and the connecting terminal portion has a narrow width, the connecting terminal portion and its periphery will inevitably lack in rigidity. Because of this, part of the connecting terminal portion may be excessively bent when it is connected to the connector.

Further, since the double-sided flexible printed wiring board may often be routed within a narrow space in an electronic apparatus, it may be bent at a steep angle near the connecting terminal portion. At this time, stress concentration may well occur in the connecting terminal portion and its vicinity, thereby causing cracks or breaks in the patterned conductors.

### BRIEF DESCRIPTION OF THE DRAWINGS'

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to a first embodiment;

FIG. 2 is an exemplary cross-sectional view showing a wiring path in a double-sided flexible printed wiring board incorporated in the portable computer of FIG. 1;

FIG. 3 is an exemplary cross-sectional view of the double-sided flexible printed wiring board according to the first embodiment, showing a state in which a first connecting terminal portion is connected to a first FPC connector;

FIG. 4 is an exemplary front view showing the area ranging from the first connecting terminal portion to a bending presumed portion in the double-sided flexible printed wiring board of the first embodiment, viewed from a first insulation layer in this printed wiring board;

FIG. 5 is an exemplary cross-sectional view of a double-sided flexible printed wiring board according to a second embodiment, showing a state in which a first connecting terminal portion is connected to a first FPC connector;

FIG. 6 is an exemplary front view showing the area ranging from the first connecting terminal portion to a bending presumed portion in the double-sided flexible printed wiring board of the second embodiment, viewed from a first insulation layer in this printed wiring board;

FIG. 7 is an exemplary front view showing the area ranging from a first connecting terminal portion to a bending presumed portion in a double-sided flexible printed wiring board according to a third embodiment, viewed from a first insulation layer in this printed wiring board;

FIG. 8 is an exemplary cross-sectional view of a double-sided flexible printed wiring board according to a fourth embodiment, showing a state in which a first connecting terminal portion is connected to a first FPC connector;

FIG. 9 is an exemplary front view showing the area ranging from the first connecting terminal portion to a bending presumed portion in the double-sided flexible printed wiring board of the fourth embodiment, viewed from a first insulation layer in this printed wiring board;

FIG. 10 is an exemplary cross-sectional view of a double-sided flexible printed wiring board according to a fifth embodiment, showing a state in which a first connecting terminal portion is connected to a first FPC connector;

FIG. 11 is an exemplary front view showing the area ranging from the first connecting terminal portion to a bending presumed portion in the double-sided flexible printed wiring board of the fifth embodiment, viewed from a first insulation layer in this printed wiring board;

FIG. 12 is an exemplary cross-sectional view of a double-sided flexible printed wiring board according to a sixth embodiment, showing a state in which a first connecting terminal portion is connected to a first FPC connector; and

FIG. 13 is an exemplary front view showing the area ranging from the first connecting terminal portion to a bending presumed portion in the double-sided flexible printed wiring board of the sixth embodiment, viewed from a first insulation layer in this printed wiring board.

### DETAILED DESCRIPTION

Various embodiments will be described hereinafter with reference to the accompanying drawings. In general, according to one embodiment, a flexible printed wiring board with a bending presumed portion continuously extending from a connecting terminal portion includes a first conductor layer formed on the first surface of an insulation base, a second conductor layer formed on the second surface of the insulation base, a first insulation layer covering the first conductor layer, and a second insulation layer covering the second conductor layer. The first insulation layer has an opening formed in a position corresponding to the connecting terminal portion to expose the first conductor layer. A metal layer is provided in a region ranging from the connecting terminal portion to the bending presumed portion. The metal layer is positioned behind the opening between the second surface of the insulation base and the second insulation layer to avoid the first conductor layer.

### First Embodiment

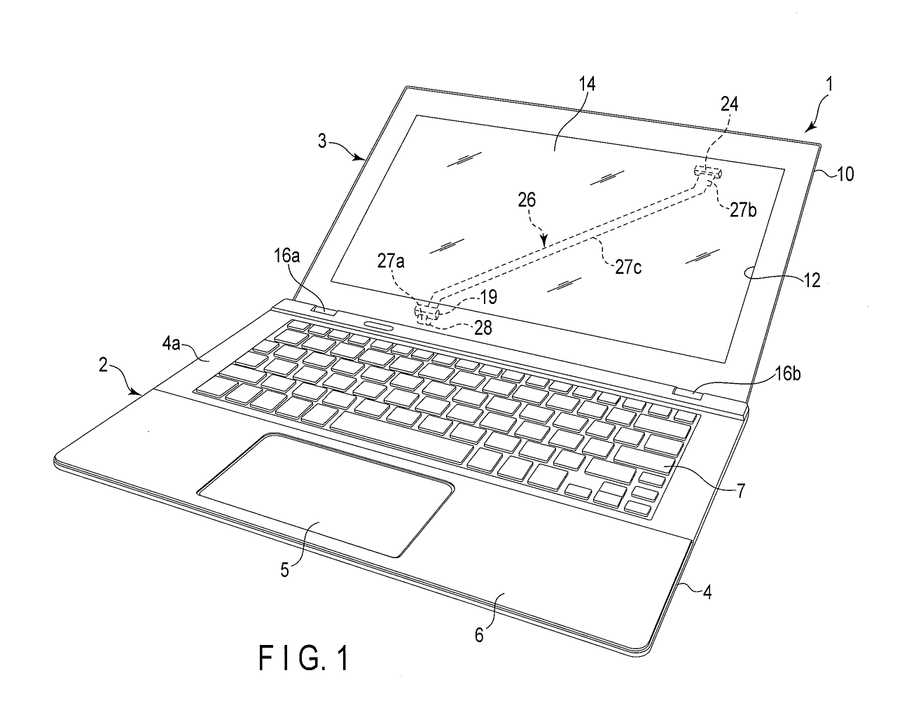

Referring now to FIGS. 1 to 4, a first embodiment will be described.

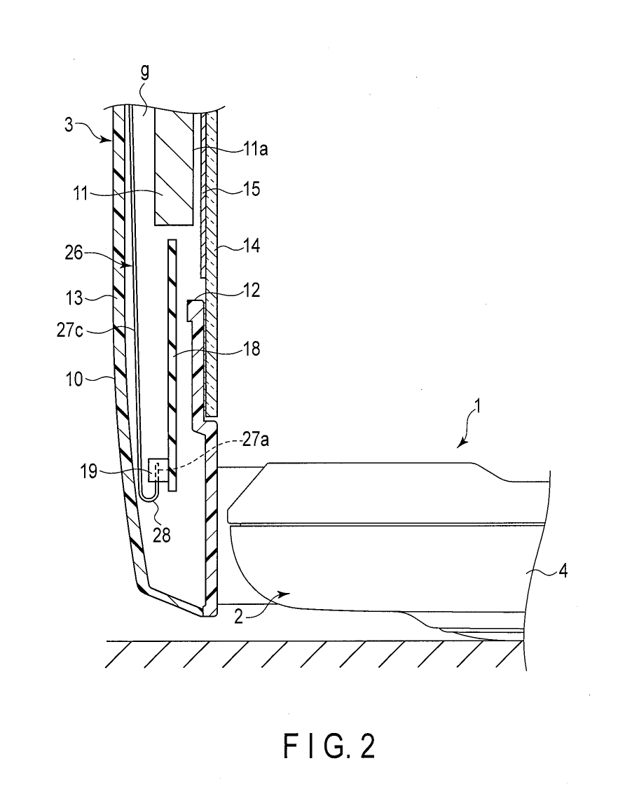

FIGS. 1 and 2 show a portable computer 1 as an example of an electronic apparatus. The portable computer 1 comprises a computer main unit 2 and a display 3. The computer main unit 2 has a first housing 4. The first housing 4 contains essential structural elements, such as a mother board with a CPU and a hard disk driving unit.

A palm rest 6 with a touch pad 5 and a keyboard 7 are provided on the upper surface 4a of the first housing 4. The keyboard 7 is located behind the palm rest 6.

The display 3 comprises a second housing 10 and a display module 11. The second housing 10 is a flat box-shaped member having the same size as the first housing 4. The second housing 10 comprises a rectangular opening 12 provided in a surface thereof, and a support wall 13 opposing the opening 12. The opening 12 is covered with a transparent surface panel 14. Further, a touch panel module 15 having a handwriting input function is attached to the reverse surface of the surface panel 14.

The display module 11 is contained in the second housing 10. The display module 11 has a display screen 11a for displaying still and video images. The display screen 11a opposes the touch panel module 15 within the second housing 10.

The display 3 is supported at the rear end of the computer main unit 2 by a pair of hinges 16a and 16b. Thus, the display 3 is set rotatable relative to the computer main unit 2 between a closed position and an open position. In the closed position, the display 3 is superposed on the computer main unit 2 to cover the palm rest 6 and the keyboard 7 from above. In the open position, the display 3 stands from the rear end of the computer main unit 2 to expose the palm rest 6, the keyboard 7 and the surface panel 14.

As shown in FIG. 2, a control board 18 for controlling the display module 11 is contained in the second housing 10. The control board 18 is positioned below the display module 11 when the display 3 is in the open position.

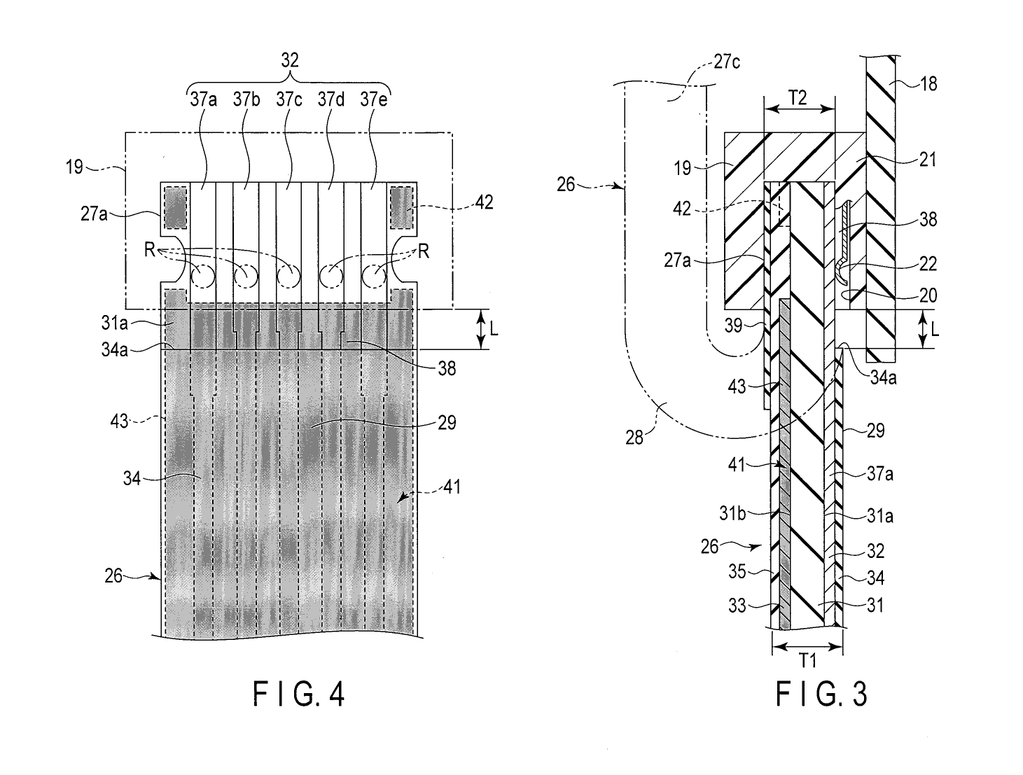

A first FPC connector 19 is mounted on the reverse surface of the control board 18. As shown in FIG. 3, the first FPC connector 19 comprises a connector main body 21 with a slot 20 formed therein, and a plurality of contact terminals 22 (only one of which is shown). The contact terminals 22 are linearly arranged at intervals.

Further, as shown in FIG. 1, a second FPC connector 24 is provided behind the display module 11. The second FPC connector 24 is mounted on the substrate of the touch panel module 15. The second FPC connector 24 is positioned near the upper portion of the display module 11 when the display 3 is in the open position, and is separate from the first FPC connector 19.

As shown in FIG. 1, the first and second FPC connectors 19 and 24 are electrically connected to each other via a double-sided flexible printed wiring board 26. The double-sided flexible printed wiring board 26 is an elongated strip element, and is passed through in a gap g between the support wall 13 of the second housing 10 and the display module 11.

The double-sided flexible printed wiring board 26 comprises a first connecting terminal portion 27a, a second connecting terminal portion 27b and an intermediate portion 27c. The first connecting terminal portion 27a is located at an end of the elongated double-sided flexible printed wiring board 26 and connected to the first FPC connector 19. The second connecting terminal portion 27b is located at the other end of the elongated double-sided flexible printed wiring board 26 and connected to the second FPC connector 24. The intermediate portion 27c couples the first and second connecting terminal portions 27a and 27b.

Further, in the first embodiment, the intermediate portion 27c of the elongated double-sided flexible printed wiring board 26 has a bent portion 28 bent arcuate. As shown in FIG. 2, the bent portion 28 is angled through substantially 180 degrees at a position adjacent to the first connecting terminal portion 27a toward the gap g between the control board 18 and the support wall 13 of the second housing 10.

In other words, the bent portion 28 is formed by folding arcuate, in the direction away from the control board 18, a bending presumed portion 29 included in the intermediate portion 27c of the double-sided flexible printed wiring board 26 and connected to the first connecting terminal portion 27a of the double-sided flexible printed wiring board 26, after connecting the first connecting terminal portion 27a to the first FPC connector 19.

In standard double-sided flexible printed wiring boards 26, the thickness T1 of the intermediate portion 27c is generally approx. 0.2 mm. In contrast, in double-sided flexible printed wiring boards 26 having a signal pattern of a designated impedance, there are increasing tendencies to have specifications in which the thickness T1 of a portion corresponding to this pattern is set to 0.2 mm or less. Similarly, in double-sided flexible printed wiring boards 26 wherein the thickness of the first and second connecting terminal portions 27a and 27b is designated, there are increasing tendencies to have specifications in which the thickness T2 of the first and second connecting terminal portions 27a and 27b is set to 0.2 mm or less.

In the embodiment, in order to satisfy the thickness specification required for the first and second FPC connectors 19 and 24, the thickness T2 of the first and second connecting terminal portions 27a and 27b is set to a value (T2≦T1) identical to or less than the thickness T1 of the intermediate portion 27c.

A description will be given of the structure of the double-sided flexible printed wiring board 26.

As shown in FIGS. 3 and 4, the double-sided flexible printed wiring board 26 mainly comprises an insulation base 31, a first conductor layer 32, a second conductor layer 33, a first insulation layer 34 and a second insulation layer 35.

The insulation base 31 is the core element of the double-sided flexible printed wiring board 26. The insulation base 31 is formed of, for example, a polyimide film, and has a freely bendable flexibility. The insulation base 31 comprises a first surface 31a as an obverse surface, and a second surface 31b as a reverse surface. Namely, the second surface 31b is positioned behind the first surface 31a.

The first conductor layer 32 is formed of, for example, copper foil. As shown in FIG. 4, the first conductor layer 32 comprises first to fifth signal lines 37a, 37b, 37c, 37d and 37e. The first to fifth signal lines 37a, 37b, 37c, 37d and 37e are arranged at intervals along the width of the insulation base 31.

In the embodiment, the second to fourth signal lines 37b, 37c and 37d are high-speed transmission lines that satisfy a high-speed data transmission characteristic of, for example, 1 G bits/s. The first signal line 37a adjacent to the second signal line 37b, and the fifth signal line 37e adjacent to the fourth signal line 37d are transmission lines having a lower data transmission rate than the second to fourth signal lines 37b, 37c and 37d. One end of each of the first to fifth signal lines 37a, 37b, 37c, 37d and 37e is led to the first connecting terminal portion 27a of the double-sided flexible printed wiring board 26. The other end of each of the first to fifth signal lines 37a, 37b, 37c, 37d and 37e is led to the second connecting terminal portion 27b of the double-sided flexible printed wiring board 26.

The second conductor layer 33 is formed of, for example, copper foil. The second conductor layer 33 is a solid pattern formed on the second surface 31b of the insulation base 31, and cooperates with the second to fourth signal lines 37b, 37c and 37d to provide high-speed transmission lines.

The second conductor layer 33 is eliminated from the regions corresponding to the first and second connecting terminal portions 27a and 27b and the bending presumed portion 29. In other words, no second conductor layer 33 exists in the regions corresponding to the first and second connecting terminal portions 27a and 27b and the bending presumed portion 29.

The first insulation layer 34 is formed of, for example, a polyimide film. As shown in FIGS. 3 and 4, the first insulation layer 34 is stacked on the first surface 31a of the insulation base 31 to cover the first to fifth signal lines 37a, 37b, 37c, 37d and 37e.

In addition, the first insulation layer 34 has an opening 38 formed in a region that ranges from the first connecting terminal portion 27a to the bending presumed portion 29. The opening 38 opens above the entire first surface 31a of the insulation base 31 in the position corresponding to the first connecting terminal portion 27a. One end of each of the first to fifth signal lines 37a, 37b, 37c, 37d and 37e is exposed to the outside of the first connecting terminal portion 27a through the opening 38.

Therefore, when the first connecting terminal portion 27a of the double-sided flexible printed wiring board 26 has been inserted in the slot 20 of the first FPC connector 19, the contact terminals 22 of the first FPC connector 19 contacts the one end of each of the first to fifth signal lines 37a, 37b, 37c, 37d and 37e in the areas indicated by reference code R in FIG. 4.

In the embodiment, where the first connecting terminal portion 27a of the double-sided flexible printed wiring board 26 is connected to the first FPC connector 19, the edge 34a of the first insulation layer 34 that defines the opening 38 is apart by a distance L from the connector main body 21 of the first FPC connector 19. Accordingly, there is no possibility of the first insulation layer 34 entering the slot 20 of the first FPC connector 19.

A similar opening 38 exists in the second connecting terminal portion 27b of the double-sided flexible printed wiring board 26. Accordingly, the other end of each of the first to fifth signal lines 37a, 37b, 37c, 37d and 37e is exposed to the outside of the second connecting terminal portion 27b through the opening 38 so that they contact the contact terminals of the second FPC connector 24.

The second insulation layer 35 is formed of, for example, a polyimide film. As shown in FIG. 3, the second insulation layer 35 is stacked on the second surface 31b of the insulation base 31 to cover the second conductor layer 33, and extends up to the first and second connecting terminal portions 27a and 27b.

As shown in FIG. 3, a reinforcing layer 39 is stacked on the second insulation layer 35. The reinforcing layer 39 is formed of, for example, a polyimide film, and extends from the first connecting terminal portion 27a to the bending presumed portion 29, thereby reinforcing this region from behind the first to fifth signal lines 37a, 37b, 37c, 37d and 37e.

The reinforcing layer 39 also functions to adjust the thickness T2 of the first connecting terminal portion 27a of the double-sided flexible printed wiring board 26. Namely, by virtue of the reinforcing layer 39, the first connecting terminal portion 27a is reliably fitted in the slot 20 of the FPC connector 19. As a result, jouncing of the first connecting terminal portion 27a relative to the first FPC connector 19 can be avoided, and the contact pressure between the contact terminals 22 of the first FPC connector 19 and the first to fifth signal lines 37a, 37b, 37c, 37d and 37e can be secured.

Another reinforcing layer 39 is provided on the region of the double-sided flexible printed wiring board 26 corresponding to the second connecting terminal portion 27b.

As shown in FIGS. 3 and 4, the double-sided flexible printed wiring board 26 further comprises a metal layer 41 extending from the first connecting terminal portion 27a to the bending presumed portion 29. The metal layer 41 is formed of, for example, copper foil of the same thickness as the second conductor layer 33. The metal layer 41 is interposed between the second surface 31b of the insulation base 31 and the second insulation layer 33, and is covered with the second insulation layer 33. In FIGS. 3 and 4, the metal layer 41 is colored in gray for facilitating its understanding.

The metal layer 41 comprises a first portion 42 incorporated in the first connecting terminal portion 27a and including two portions, and a second portion 43 incorporated in the bending presumed portion 29. The two portions of the first portion 42 are provided behind the opening 38 at opposite widthwise portions of the first connecting terminal portion 27a so as to avoid the one end of each of the first to fifth signal lines 37a, 37b, 37c, 37d and 37e exposed through the opening 38. As a result, no metal layer 41 exists behind contact areas R where the contact terminals 22 contact the first to fifth signal lines 37a, 37b, 37c, 37d and 37e.

The second portion 43 covers the entire second surface 31b at the position corresponding to the bending presumed portion 29. The second portion 43 may be electrically connected to or disconnected from the second conductor layer 33.

In the first embodiment, when the first connecting terminal portion 27a of the double-sided flexible printed wiring board 26 is connected to the first FPC connector 19, the second portion 43 of the metal layer 41 is positioned in the region ranging from the first connecting terminal portion 27a to the bending presumed portion 29 as shown in FIG. 3. Accordingly, the rigidity of the bending presumed portion 29 of the double-sided flexible printed wiring board 26 led through the slot 20 of the first FPC connector 19 is increased, whereby the bending presumed portion 29 is prevented from being bent at a steep angle, when the bending presumed portion 29 is folded through 180 degrees to form an arcuate bent portion 28 as indicated by the two-dot chain lines in FIG. 3. In other words, the bending presumed portion 29 can be smoothly curved with a large curvature so as not to break the bending presumed portion 29.

As a result, local concentration of tension stress on the insulation base 31 and the first to fifth signal lines 37a, 37b, 37c, 37d and 37e at the position of the bent portion 28 can be avoided. This prevents cracks in the insulation base 31 and/or breakage of the first to fifth signal lines 37a, 37b, 37c, 37d and 37e, whereby a double-sided flexible printed wiring board 26 exhibiting a high bending resistance can be obtained.

Moreover, since the first portion 42 of the metal layer 41 reinforces the first connecting terminal portion 27a behind the opening 38, the first connecting terminal portion 27a is hard to bend when it is inserted into the slot 20 of the first FPC connector 27a. This means that the working of connecting the first connecting terminal portion 27a to the first FPC connector 19 can be performed easily.

Furthermore, the two portions of the first portion 42 of the metal layer 41 are deviated, when viewed from behind, from the portions of the first to fifth signal lines 37a, 37b, 37c, 37d and 37e exposed through the opening 38. Therefore, although the first connecting terminal portion 27a is reinforced by the metal layer 41, this does not adversely affect the characteristic impedances of the second to fourth signal lines 37b, 37c and 37d that constitute high-speed signal lines.

In addition, by virtue of the existence of the metal layer 41, the second insulation layer 35 and the reinforcing layer 39 can be thinned. Therefore, the rigidity of the first connecting terminal portion 27a and its periphery can be secured without increasing the thicknesses of the first connecting terminal portion 27a and the bending presumed portion 29.

In the first embodiment, the metal layer 41 is formed of copper foil. However, the material of the metal layer 41 is not limited to copper foil, but may be a metal paste, such as silver or copper paste. This metal paste may be printed on the second surface 31b of the insulation base 31.

### Second Embodiment

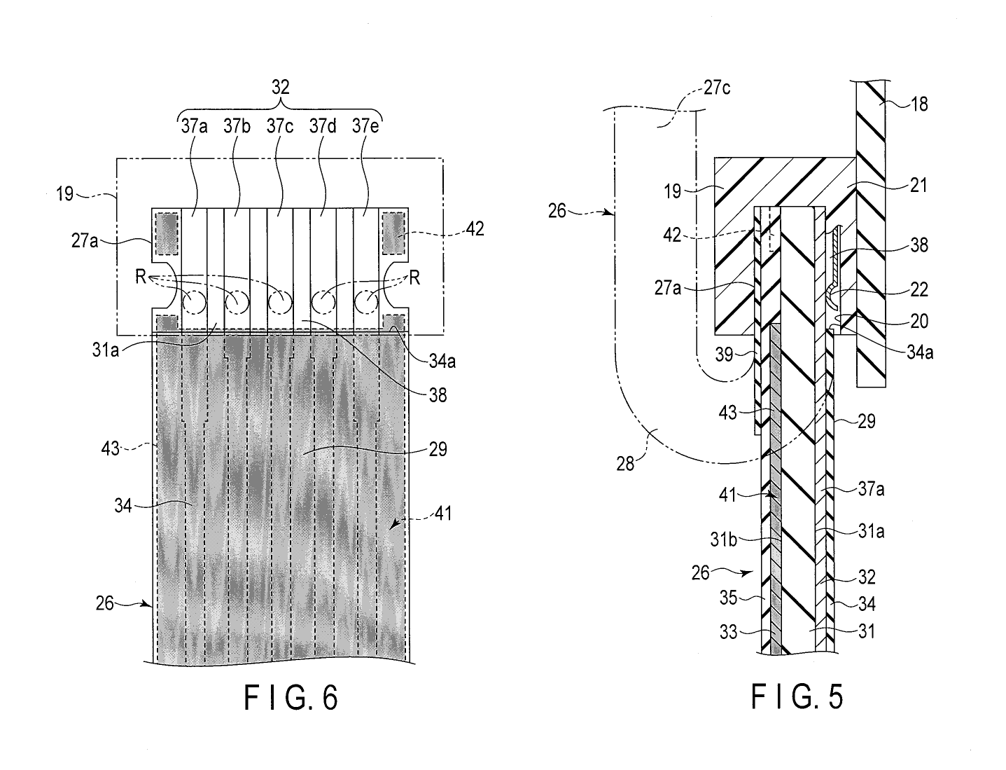

FIGS. 5 and 6 show a second embodiment. The second embodiment differs from the first embodiment in the matter associated with the second insulation layer 35. Since in the second embodiment, the basic structure of the double-sided flexible printed wiring board 26 other than the above point is similar to that of the first embodiment, elements similar to those of the first embodiment are denoted by corresponding reference numbers, and no detailed description will be given thereof.

In the second embodiment, the first insulation layer 34 is extended from the bending presumed portion 29 to the first connecting terminal portion 27a. Accordingly, in the second embodiment, the opening 38 is narrowed compared to the first embodiment. More specifically, as shown in FIG. 5, in a state in which the first connecting terminal portion 27a of the double-sided flexible printed wiring board 26 is inserted in the slot 20 of the first FPC connector 19, the edge 34a of the first insulation layer 34 that defines the opening 38 is positioned at the open end of the slot 20.

This means that the first insulation layer 34 is extended to the region where it does not adversely affect the thickness of the first FPC connector 19 when the first connecting terminal portion 27a is connected to the first FPC connector 19.

Since in the second embodiment, the first insulation layer 34 reaches the open end of the slot 20 of the first FPC connector 19, the region ranging from the first connecting terminal portion 27a to the bending presumed portion 29 can be reinforced using the first insulation layer 34. As a result, when the bending presumed portion 29 of the double-sided flexible printed wiring board 26 is folded through 180 degrees to form the arcuate bent portion 28, it is prevented from being bent at a steep angle. Thus, a double-sided flexible printed wiring board 26 exhibiting a high bending resistance can be obtained.

### Third Embodiment

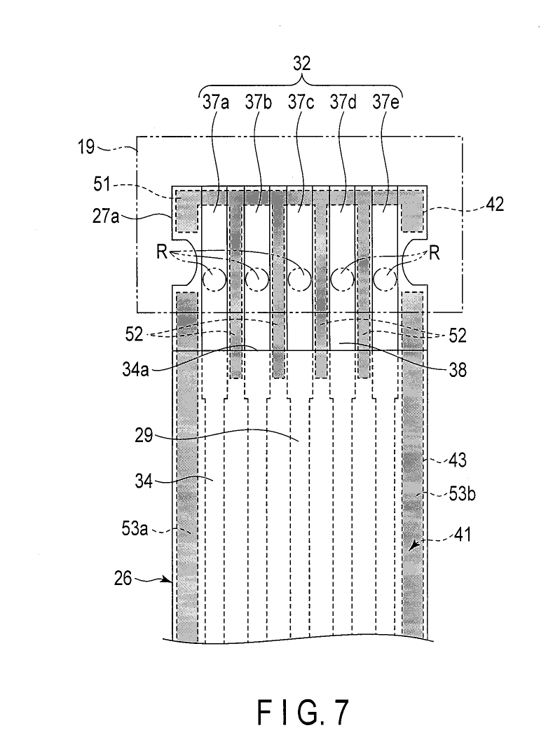

FIG. 7 shows a third embodiment. The third embodiment differs from the first embodiment mainly in the matter associated with the metal layer 41. Since in the third embodiment, the basic structure of the double-sided flexible printed wiring board 26 other than the above point is similar to that of the first embodiment, elements similar to those of the first embodiment are denoted by corresponding reference numbers, and no detailed description will be given thereof.

In the third embodiment, all of the first to fifth signal lines 37a, 37b, 37c, 37d and 37e are transmission lines having a lower data transmission rate than the second to fourth signal lines 37b, 37c and 37d of the first embodiment.

On the other hand, the first portion 42 of the metal layer 41 comprises an outer peripheral portion 51 provided along the outer periphery of the first connecting terminal portion 27a, and a plurality of extensions 52 branching from the outer peripheral portion 51. The outer peripheral portion 51 surrounds one end of each of the first to fifth signal lines 37a, 37b, 37c, 37d and 37e exposed through the opening 38 behind the opening 38. The extensions 52 linearly extend from the distal end of the first connecting terminal portion 27a to the bending presumed portion 29 at regular intervals such that the extensions and the first to fifth signal lines 37a, 37b, 37c, 37d and 37e are alternately arranged. The extensions 52 reach the bending presumed portion 29.

The second portion 43 of the metal layer 41 comprises a pair of linear portions 53a and 53b. The linear portions 53a and 53b longitudinally extend along both edges of the double-sided flexible printed wiring board 26, and do not overlap the first to fifth signal lines 37a, 37b, 37c, 37d and 37e.

As shown in FIG. 7, where the first connecting terminal portion 27a of the double-sided flexible printed wiring board 26 is connected to the first FPC connector 19, the distal ends of the extensions 52 and the ends of the linear portions 53a and 53b are positioned in the boundary region of the first connecting terminal portion 27a and the bending presumed portion 29.

In the third embodiment, the first portion 42 of the metal layer 41 comprises the outer peripheral portion 51 that surrounds one end of each of the first to fifth signal lines 37a, 37b, 37c, 37d and 37e behind the opening 38, and the plurality of extensions 52 each arranged between a corresponding pair of adjacent ends of the first to fifth signal lines 37a, 37b, 37c, 37d and 37e behind the opening 38.

By virtue of this structure, the first connecting terminal portion 27a, at which one end of each of the first to fifth signal lines 37a, 37b, 37c, 37d and 37e are exposed, can be reinforced by the metal layer 41 from behind the opening 38, thereby imparting a sufficient rigidity to the first connecting terminal portion 27a. This structure enables the first connecting terminal portion 27a to be easily connected to the first FPC connector 19.

Moreover, since the distal ends of the extensions 52 and the ends of the linear portions 53a and 53b are positioned in the boundary region of the first connecting terminal portion 27a and the bending presumed portion 29, the region ranging from the first connecting terminal portion 27a to the bending presumed portion 29 can be reinforced by the distal ends of the extensions 52 and the ends of the linear portions 53a and 53b. As a result, when the bending presumed portion 29 of the double-sided flexible printed wiring board 26 is folded through 180 degrees to form the arcuate bent portion 28, it is prevented from being bent at a steep angle. Thus, a double-sided flexible printed wiring board 26 exhibiting a high bending resistance can be obtained.

### Fourth Embodiment

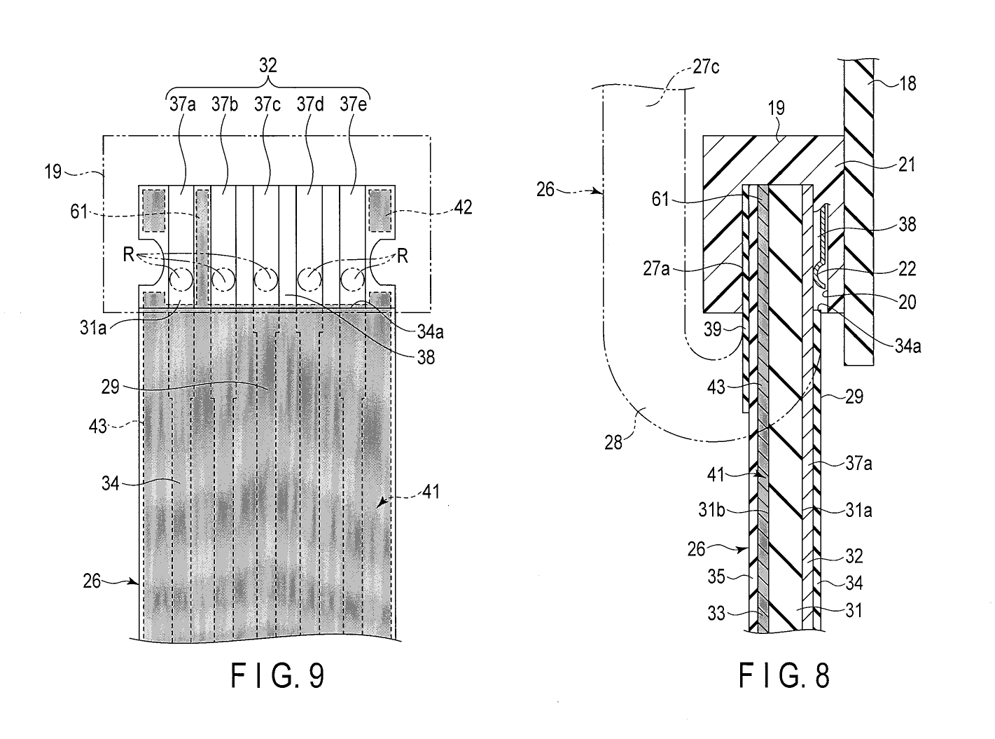

FIGS. 8 and 9 show a fourth embodiment. The fourth embodiment differs from the first embodiment mainly in the matter associated with the second insulation layer 35 and the metal layer 41. Since in the fourth embodiment, the basic structure of the double-sided flexible printed wiring board 26 other than the above point is similar to that of the first embodiment, elements similar to those of the first embodiment are denoted by corresponding reference numbers, and no detailed description will be given thereof.

In the fourth embodiment, the third and fourth signal lines 37c and 37d are high-speed transmission lines that satisfy the same high-speed transmission characteristic as that of the first embodiment, and the remaining first, second and fifth signal lines 37a, 37b and 37e are transmission lines having a lower data transmission rate than the third and fourth signal lines 37c and 37d.

Further, in the fourth embodiment, the first insulation layer 34 is extended from the bending presumed portion 29 to the first connecting terminal portion 27a. Accordingly, in the fourth embodiment, the opening 38 is narrowed compared to the first embodiment. More specifically, as shown in FIG. 8, in a state in which the first connecting terminal portion 27a of the double-sided flexible printed wiring board 26 is inserted in the slot 20 of the first FPC connector 19, the edge 34a of the first insulation layer 34 that defines the opening 38 is positioned at the open end of the slot 20.

This means that the first insulation layer 34 is extended to the region where it does not adversely affect the thickness of the first FPC connector 19 when the first connecting terminal portion 27a is connected to the first FPC connector 19.

As shown in FIG. 9, the metal layer 41 includes a single extension 61. The extension 61 extends behind the opening 38 along the second surface 31b of the insulation base 31 between the first and second signal lines 37a and 37b. The extension 61 directly extends from the bending presumed portion 29 to the end of first connecting terminal portion 27a away from the third and fourth signal lines 37c and 37d as high-speed signal lines. Accordingly, the extension 61 does not adversely affect the characteristic impedance of the third or fourth signal line 37c or 37d.

In the fourth embodiment, the first insulation layer 34 is extended from the bending presumed portion 29 to the first connecting terminal portion 27a, and hence the opening 38 is narrowed compared to the first embodiment. More specifically, as shown in FIG. 8, in a state in which the first connecting terminal portion 27a of the double-sided flexible printed wiring board 26 is inserted in the slot 20 of the first FPC connector 19, the edge 34a of the first insulation layer 34 that defines the opening 38 is positioned at the open end of the slot 20.

This means that the first insulation layer 34 is extended to the region where it does not adversely affect the thickness of the first FPC connector 19 when the first connecting terminal portion 27a is connected to the first FPC connector 19. Therefore, the region ranging from the first connecting terminal portion 27a to the bending presumed portion 29 can be reinforced using the first insulation layer 34.

Further, in the fourth embodiment, the metal layer 41 includes the single extension 61 positioned behind the opening 38 between the first and second signal lines 37a and 37b. The extension 61 reinforces, from behind the opening 38, the first connecting terminal portion 27a of the double-sided flexible printed wiring board 26.

The above structure imparts a sufficient rigidity to the first connecting terminal portion 27a and its periphery, along with the extended first insulation layer 34.

In addition, the second portion 43 and the extension 61 of the metal layer 41 reinforce the region ranging from the first connecting terminal portion 27a to the bending presumed portion 29. As a result, when the bending presumed portion 29 of the double-sided flexible printed wiring board 26 is folded through 180 degrees to form the arcuate bent portion 28, it is prevented from being bent at a steep angle. Thus, a double-sided flexible printed wiring board 26 exhibiting a high bending resistance can be obtained.

### Fifth Embodiment

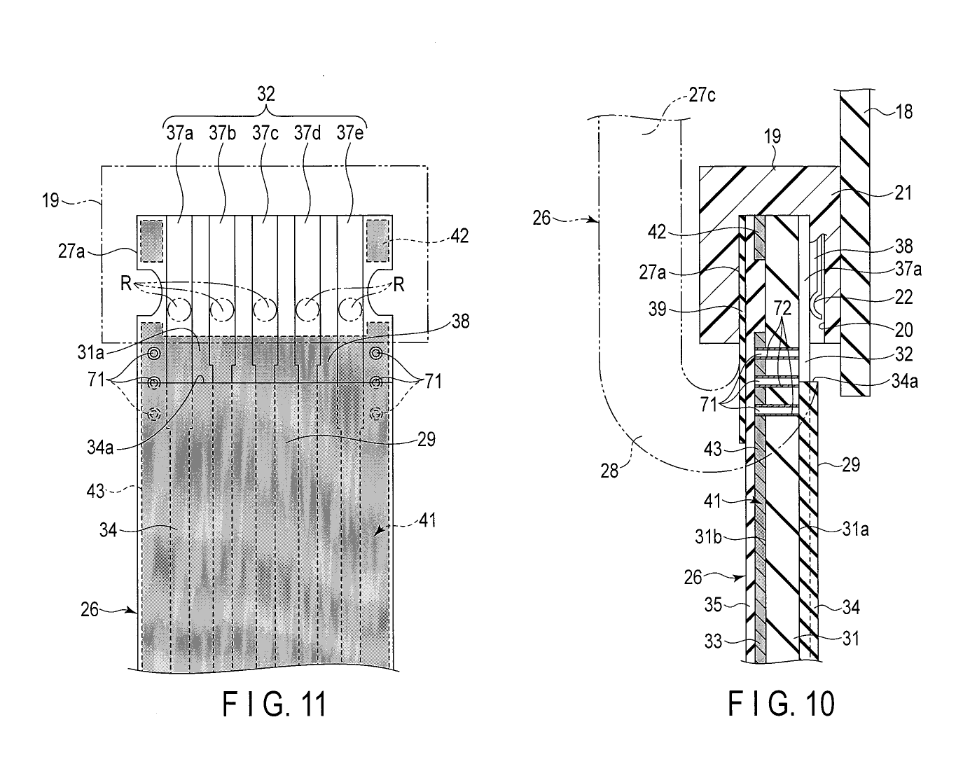

FIGS. 10 and 11 show a fifth embodiment. The fifth embodiment is obtained by further developing the first embodiment, and the basic structure of the double-sided flexible printed wiring board 26 is similar to that of the first embodiment. Therefore, in the fifth embodiment, elements similar to those of the first embodiment are denoted by corresponding reference numbers, and no detailed description will be given thereof.

As shown in FIGS. 10 and 11, a plurality of through holes 71 are provided in the bending presumed portion 29 of the double-sided flexible printed wiring board 26. The through holes 71 are formed by, for example, drilling the insulation base 31 and the metal layer 41, and are formed through the insulation base 31 and the metal layer 41 along the thickness of the double-sided flexible printed wiring board 26.

The through holes 71 are arranged at regular intervals along both edges of the double-sided flexible printed wiring board 26, deviated from the first to fifth signal lines 37a, 37b, 37c, 37d and 37e. Further, the walls of the through holes 71 are covered with plated layers 72 electrically connected to the metal layer 41.

As shown in FIG. 10, in a state in which the first connecting terminal portion 27a of the double-sided flexible printed wiring board 26 is inserted in the slot 20 of the first FPC connector 19, the through holes 71 are positioned outside the first FPC connector 19. Namely, the bending presumed portion 29 of the double-sided flexible printed wiring board 26, which is positioned closest to the first FPC connector 19, is reinforced from inside by the plated layers 72 of the through holes 71, and hence has a higher rigidity.

Therefore, when the bending presumed portion 29 of the double-sided flexible printed wiring board 26 is folded through 180 degrees to form the arcuate bent portion 28, it is prevented from being bent at a steep angle, as is indicated by the two-dot chain lines in FIG. 10. Thus, a double-sided flexible printed wiring board 26 exhibiting a high bending resistance can be obtained.

### Sixth Embodiment

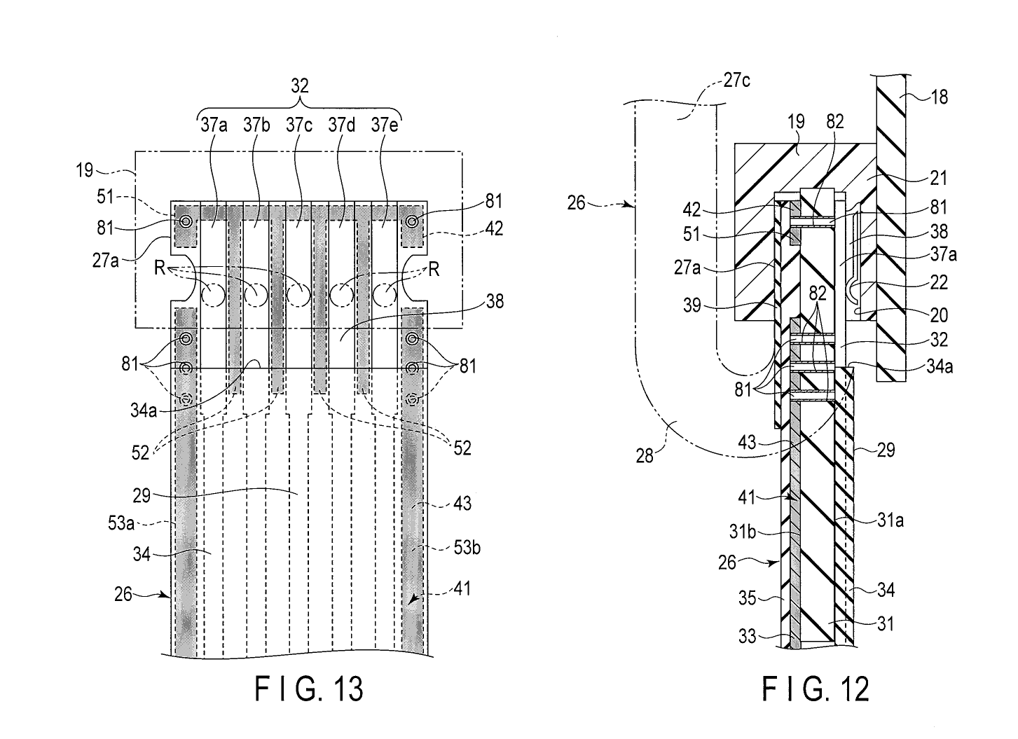

FIGS. 12 and 13 show a sixth embodiment. The sixth embodiment is obtained by further developing the third embodiment, and the basic structure of the double-sided flexible printed wiring board 26 is similar to that of the third embodiment. Therefore, in the sixth embodiment, elements similar to those of the third embodiment are denoted by corresponding reference numbers, and no detailed description will be given thereof.

A plurality of through holes 81 are provided in the region ranging from the first connecting terminal portion 27a of the double-sided flexible printed wiring board 26 to the bending presumed portion 29 thereof. The through holes 81 are formed by, for example, drilling the insulation base 31 and the metal layer 41, and are formed through the insulation base 31 and the metal layer 41 along the thickness of the double-sided flexible printed wiring board 26.

The through holes 81 are arranged at intervals along both edges of the double-sided flexible printed wiring board 26, deviated from the first to fifth signal lines 37a, 37b, 37c, 37d and 37e. In the first connecting terminal portion 27a and a pair of through holes 81 are formed in the end of the same.

Further, the walls of the through holes 81 are covered with plated layers 82 electrically connected to the metal layer 41.

As shown in FIG. 12, in a state in which the first connecting terminal portion 27a of the double-sided flexible printed wiring board 26 is inserted in the slot 20 of the first FPC connector 19, the through holes 81 except for the above-mentioned pair of through holes 81 are positioned outside the first FPC connector 19. Namely, the bending presumed portion 29 of the double-sided flexible printed wiring board 26, which is positioned closest to the first FPC connector 19, is reinforced from inside by the plated layers 82 of the through holes 81, and hence has a higher rigidity.

Therefore, when the bending presumed portion 29 of the double-sided flexible printed wiring board 26 is folded through 180 degrees to form the arcuate bent portion 28, it is prevented from being bent at a steep angle, as is indicated by the two-dot chain lines in FIG. 12. Thus, a double-sided flexible printed wiring board 26 exhibiting a high bending resistance can be obtained.

Furthermore, the end of the first connecting terminal portion 27a is also reinforced from inside by the pair of through holes 81, thereby increasing the rigidity of the first connecting terminal portion 27a. This structure enables the first connecting terminal portion 27a to be easily connected to the first FPC connector 19.

Although in the fifth and sixth embodiments, the rigidity of the first connecting terminal portion 27a and the bending presumed portion 29 is increased by the plated layers 72 and 82 formed on the walls of the through holes 71 and 81, the invention is not limited to this. For instance, the rigidity of the first connecting terminal portion 27a and the bending presumed portion 29 may be enhanced by filling the through holes 71 and 81 with solder or a metal paste.

In addition, the through holes are not limited to those formed in the insulation base 31 and the metal layer 41 along the thickness of the double-sided flexible printed wiring board 26. Alternatively, blind via holes having bottoms may be formed. The blind via holes can be formed by irradiating the insulation base 31 and the metal layer 41 with a laser beam or ultraviolet light.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A flexible printed wiring board including a connecting terminal portion connected to a connector, and a bending presumed portion continuously extending from the connecting terminal portion, comprising:
an insulation base including a first surface and a second surface as a back surface;
a first conductor layer formed on the first surface of the insulation base;
a second conductor layer formed on the second surface of the insulation base;
a first insulation layer formed on the first surface of the insulation base to cover the first conductor layer, and having an opening formed in a position corresponding to the connecting terminal portion to expose the first conductor layer;
a second insulation layer formed on the second surface of the insulation base to cover the second conductor layer; and
a metal layer provided in a region ranging from the connecting terminal portion to the bending presumed portion, the metal layer being positioned behind the opening between the second surface of the insulation base and the second insulation layer to avoid the first conductor layer exposed through the opening.

2. The flexible printed wiring board of claim 1, wherein the first conductor layer includes a plurality of signal lines, at least one of the signal lines cooperating with the second conductor to form a high-speed transmission line.

3. The flexible printed wiring board of claim 2, wherein the metal layer is electrically connected to the second conductor layer.

4. The flexible printed wiring board of claim 1, wherein
the first conductor layer includes a plurality of signal lines arranged at intervals; and
the metal layer has at least one extension positioned behind the opening between the signal lines.

5. The flexible printed wiring board of claim 1, wherein
the first conductor layer includes a plurality of signal lines arranged at intervals;
at least one of the signal lines cooperates with the second conductor to form a high-speed transmission line; and
the metal layer has an extension positioned behind the opening between signal lines included in the plurality of signal lines and excluding the at least one signal line forming the high-speed transmission line.

6. The flexible printed wiring board of claim 1, wherein the metal layer is copper foil.

7. The flexible printed wiring board of claim 1, further comprising a reinforcing layer formed on the second insulation layer in a region corresponding to the connecting terminal portion and the bending presumed portion.

8. A flexible printed wiring board including a connecting terminal portion connected to a connector, and a bending presumed portion continuously extending from the connecting terminal portion, comprising:
an insulation base including a first surface and a second surface as a back surface;
a first conductor layer formed on the first surface of the insulation base;
a second conductor layer formed on the second surface of the insulation base;
a first insulation layer formed on the first surface of the insulation base to cover the first conductor layer, and having an opening formed in a position corresponding to the connecting terminal portion to expose the first conductor layer;
a second insulation layer formed on the second surface of the insulation base to cover the second conductor layer;
a metal layer provided in a region ranging from the connecting terminal portion to the bending presumed portion, the metal layer being positioned behind the opening between the second surface of the insulation base and the second insulation layer to avoid the first conductor layer exposed through the opening; and
a plurality of through holes formed at least in the bending presumed portion between the insulation base and the metal layer to avoid the first conductor layer.

9. The flexible printed wiring board of claim 8, wherein the through holes have plated wall surfaces.

10. The flexible printed wiring board of claim 8, wherein the through holes are arranged at intervals along a length of the insulation base.

11. The flexible printed wiring board of claim 8, wherein the through holes are provided in a region ranging from the connecting terminal portion to the bending presumed portion.

12. The flexible printed wiring board of claim 8, further comprising a reinforcing layer formed on the second insulation layer in a region corresponding to the connecting terminal portion and the bending presumed portion.

13. The flexible printed wiring board of claim 8, wherein the first conductor layer includes a plurality of signal lines, at least one of the signal lines cooperating with the second conductor to form a high-speed transmission line.

14. The flexible printed wiring board of claim 13, wherein the metal layer is electrically connected to the second conductor layer.

15. An electronic apparatus comprising:
a housing; and
a flexible printed wiring board provided in the housing, the flexible printed wiring board including a connecting terminal portion connected to a connector, and a bent portion adjacent to the connecting terminal portion and bent arcuate,
wherein the flexible printed wiring board comprises:
an insulation base including a first surface and a second surface as a back surface;
a first conductor layer formed on the first surface of the insulation base;
a second conductor layer formed on the second surface of the insulation base;
a first insulation layer formed on the first surface of the insulation base to cover the first conductor layer, and having an opening formed in a position corresponding to the connecting terminal portion to expose the first conductor layer;
a second insulation layer formed on the second surface of the insulation base to cover the second conductor layer; and
a metal layer provided in a region ranging from the connecting terminal portion to the bending presumed portion, the metal layer being positioned behind the opening between the second surface of the insulation base and the second insulation layer to avoid the first conductor layer exposed through the opening.
